(19) United States
(12) Patent Application Publication
(10) Pub. No.: US 2007/0196935 A1
(43) Pub. Date: Aug. 23, 2007

(54) Prediction of ESL/ILD remaining thickness

(75) Inventors: Tang Kok Hiang, Singapore (SG); Ming-Ta Lei, Hsin-Chu (TW); Yung-Chih Wang, Taoyuan (TW); Chia Hsing Huang, Hsinchu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/412,005

(22) Filed: Apr. 26, 2006

Related U.S. Application Data
(60) Provisional application No. 60/774,418, filed on Feb. 17, 2006.

(51) Int. Cl. H01L 21/66

(52) U.S. Cl. 438/14; 438/16

(57) ABSTRACT

A method for determining a remaining thickness of a dielectric layer at the bottom of an opening in an integrated circuit is provided. The method includes providing a substrate, forming a dielectric layer over the substrate, forming an opening in the dielectric layer, grounding the substrate, scanning the substrate using a scanning electron microscope to produce a voltage contrast (VC) image, determining a gray level of the opening in the VC image, and using the gray level to determine a remaining thickness of the dielectric layer at the bottom of the opening.

This application claims priority to provisional patent application serial no. 60/774,418, filed Feb. 17, 2006, and entitled “Prediction of ESL/ILD Remaining Thickness,” which application is hereby incorporated herein by reference.

### TECHNICAL FIELD

This invention relates generally to inline monitoring of via/contact etching processes in the fabrication of integrated circuits, and more particularly to methods for determining the remaining thickness of the dielectric layer at the bottom of via/contact openings by using a scanning electron microscope (SEM).

### BACKGROUND

Very large-scale integrated (VLSI) circuits rely on via/contact openings (as well as trenches) for electrically interconnecting devices in different regions or interconnecting one layer to another. Reliable etching processes are required for forming via or contact openings. However, the defects associated with the deep sub-micron via/contact opening formation make up a significant portion of the total yield loss. Therefore, it is essential to ensure that the etching process for creating via/contact openings is optimized and controlled within the process window, and that the potential via/contact failure due to either process parameters shifting or wafer-to-wafer dielectric thickness variation can be identified and avoided in the early stages of production.

Because of the non-uniformity in the etch rate, and the fact that the film itself may be of non-uniform thickness across the wafer or from wafer to wafer, a certain amount of over-etching is conducted to ensure that complete etching is achieved throughout the wafer, and thus appropriate electrical contacts are obtained. Typically, this is achieved by an over-etching process, which is often about 10 to 20 percent in terms of time past the endpoint. Even more over-etching (as much as 50%) may be required when anisotropic processing is done over non-planar topography. However, with the scaling of the integrated circuits, the over-etch margins have dropped drastically. Due to the limited selectivity of the etch process, excessive over-etch of contact openings will cause the underlying layers, for example, the thin metal silicide layer on top of a drain/source region, to be diminished. Additionally, there is high probability that a contact will penetrate the shallow p-n junction beneath the drain/source region. For via etch processes aimed at opening dielectric barriers over the lower metal level, it is also necessary to avoid excessive dielectric barrier over-etch. Otherwise, copper may be exposed and sputtered during the over-etch step, potentially compromising device reliability.

Conventionally, the process of etching vias/contacts can be monitored by measuring the resistance of long chains connecting thousands of vias/contacts in series with each other, wherein the vias/contacts are typically located in the scribe lines to save chip space, or in sample chips on the wafer. A current is passed through the long chains, and the measured voltage is a measure of the average contact resistance. These structures are used to monitor the processing conditions and structures and to measure lot-to-lot variations.

This method suffers drawbacks, however. A high resistance in these structures could indicate a problem that could occur for a variety of reasons, such as under-etch, over-etch, and/or etch residue, poor metal deposition, voids in the contact region, or other problems incurred in subsequent processes. The under-etch/over-etch cannot be identified with reasonable confidence. In addition, this test cannot be performed before completion of the conductive wiring chain. This increases the manufacturing cost.

An electron beam inspection system, or in its simplest form, a scanning electron microscope (SEM), has been proven to be a powerful tool for imaging electrical defects such as via/contact shorts. As the primary electron beam scans over the inspection area, low energy secondary electrons (SE) (˜5 eV) will be generated from the surface and collected by the SE detector to form an image. Due to the differences in SE yields of the involved materials or the abnormal electrical conductivity of the defect portions, the inspected surface will be unevenly charged positively and/or negatively. Negatively charged surfaces tend to produce more SE to the signal detector, thus its appearance is relatively brighter, while a positively charged surface attracts more SE and thus appears relatively darker. This is the so-called voltage contrast (VC). VC can be used roughly to divide via/contact openings into the categories of under-etch or over-etch. However, it lacks the sensitivity to distinguish the severity of under-etch or over-etch, thus is not suitable for advanced process monitoring.

U.S. Pat. No. 6,815,345 discusses a method and devices for determining whether via/contact holes are over-etched or under-etched in the process of fabricating a semiconductor device. A sample structure for monitoring the via/contact openings is included, wherein the sample structure includes via/contact holes of different sizes and densities formed in a dielectric layer. The thickness of the dielectric layer as well as its topography resembles that required in the functional dies for making actual devices. The via/contact holes in the sample structure, formed simultaneously with those in the functional die, will be etched to different levels as the result of the micro-loading effects. Voltage contrast of these holes will reverse at certain beam conditions from bright to dark if the thickness of under-etch remains over a threshold value at a certain primary beam energy and current.

The method provided by U.S. Pat. No. 6,815,345 can be used for determining whether over-etch or under-etch occurs, including the case where the dielectric layer is etched-through and the case where a thick layer remains. It cannot be used to quantify the over-etch or under-etch, however. When there is a thin layer remaining, particularly a thin layer with a thickness less than about 50 Å, the thickness of the remaining layer cannot be determined. However, to precisely adjust etching processes, the remaining thickness at the bottom of the via/contact openings has to be known. A novel method that can provide a more accurate view of the etching process, therefore, is needed.

### SUMMARY OF THE INVENTION

In accordance with one aspect of the present invention, a method for determining the thickness of the remaining dielectric layer at the bottom of a via/contact opening includes providing a substrate, forming a dielectric layer over the substrate, forming an opening in the dielectric layer, grounding the substrate and scanning the substrate using a scanning electron microscope to produce a voltage contrast (VC) image, determining a gray level of the opening in the VC image, and using the gray level to determine the thickness of the remaining dielectric layer at the bottom of the opening.

In accordance with another aspect of the present invention, a calibration process is performed to construe a correlation between the gray levels and the remaining thicknesses. The calibration process includes forming sample openings substantially similar to the via/contact opening, using a scanning electron microscope to produce VC images of the sample openings, determining gray levels of the sample openings from the VC images, measuring the remaining thicknesses of the sample openings, and establishing the correlation using the gray levels and the remaining thicknesses.

An advantageous feature of the present invention is that quick feedback for process optimization can be provided. Another advantageous feature of the present invention is that the method provided is non-destructive. A further advantageous feature of the present invention is that a remaining thickness of less than about 50 Å can be determined.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a semiconductor structure having two via openings formed in a dielectric layer, wherein the two via openings have different remaining thicknesses;

FIG. 2 illustrates a schematic charge distribution in the structure shown in FIG. 1;

FIG. 3 illustrates a sample calibration curve obtained from experiment results;

FIG. 4 illustrates a contact opening with a thin contact etch stop layer remaining; and

FIG. 5 illustrates a via/contact opening with a thick dielectric layer remaining at the bottom, wherein the thickness of the remaining dielectric layer can be determined using the preferred embodiments of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

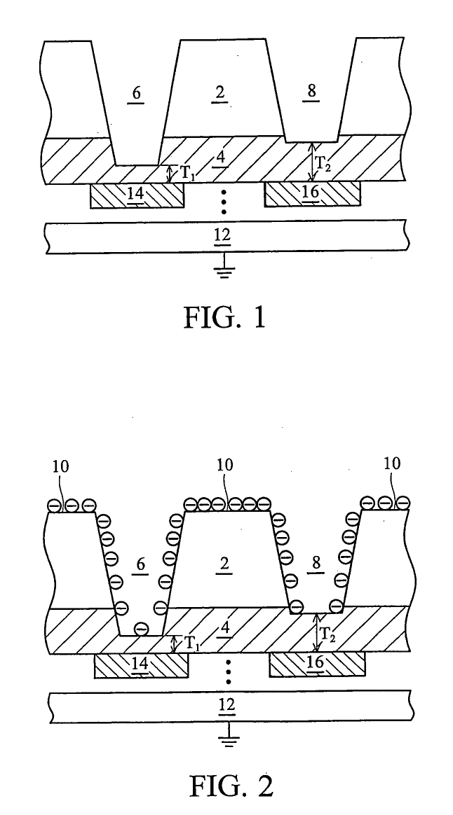

FIG. 1 illustrates two conductive features 14 and 16 formed over a substrate 12. The conductive features 14 and 16 may be silicide regions over source/drain regions, gate electrodes, doped regions, metal lines in a metallization layer, and the like. A contact etch stop layer (CESL) 4 is formed on the conductive features 14 and 16, followed by the formation of a dielectric layer 2. In the preferred embodiment, dielectric layer 2 is an inter-metal dielectric (IMD) layer, which preferably has a low-k dielectric constant (k value). In other embodiments, dielectric layer 2 is an inter-layer dielectric (ILD) layer. Note that for illustration purposes, the features are not drawn to scale.

FIG. 1 shows an intermediate stage during the formation of via openings 6 and 8, which are used for interconnecting conductive features 14 and 16 to subsequently formed overlying interconnections. After etching the dielectric layer 2, the etching stops at the CESL 4. Due to process variations, for example, micro-loading effects caused by pattern density differences, via 6 and via 8 extend into the CESL 4 for different depths. At the bottoms of via openings 6 and 8, CESL 4 remains, wherein the remaining thicknesses are T₁ and T₂ for via openings 6 and 8, respectively. For simplicity, throughout the description, the thickness of the remaining dielectric layer at the bottom of a via is referred to as the remaining thickness.

The CESL 4 will then be etched. Since CESL 4 is thin, a small process variation may make a big difference. For example, over-etching CESL 4 may cause the underlying silicide region to be etched. In order to precisely control the etching process, the remaining thickness of the CESL 4 needs to be determined.

In the preferred embodiment, the wafer on which the structure shown in FIG. 1 is formed is scanned with an eBeam using a scanning electron microscope (SEM). Secondary electrons are generated and emitted from the surfaces of the wafer. The data of the secondary electrons is converted to a voltage contrast (VC) image, which shows the brightness of the respective features on the wafer. Throughout the description, a term “gray level” is alternatively used to indicate the brightness, wherein a high gray level represents a high brightness.

In an exemplary embodiment, the eBeam has a landing energy of greater than 50 eV and less than maximum sustainable landing energy, which is limited by the hardware providing the eBeam. The landing energy may be adjusted depending on the material of the CESL 4 and the remaining thickness T₁ and T₂, so that the gray levels can be brought into a desired range.

When scanning is performed, the substrate 12 (or the back of the wafer) is preferably grounded. Throughout the description, the term “grounded” is used to refer to a feature being connected to the electrical ground or being virtually grounded. When a feature has a relatively high capacity for storing charge, so that during eBeam scanning the potential of the respective feature is substantially stable, the feature is considered to be virtually grounded, although it is not necessarily connected to the electrical ground. If the leakage current is very small, the underlying regions 14 and 16 can be treated as virtually grounded. In this case, the bottom of the via openings are separated from the virtual ground only by a thin CESL.

During the eBeam scanning, the surface voltage varies with the amount of surface-accumulated charges. The ability to sustain charges, hence the surface voltage, of the region being scanned is associated with the material and structure of the underlying materials. FIG. 2 schematically illustrates an exemplary charge accumulation on the surfaces of the structure shown in FIG. 1. Since dielectric layer 2 and CESL 4 are dielectric layers, accumulated charges cannot flow freely on their respective surfaces. The distribution of charges on the surfaces is different from one location to another due to the topology difference. For example, more electrons are accumulated on the top surface of dielectric layer 2, while less electrons are accumulated at the bottom of the via openings 6 and 8. A possible explanation is that at the bottom of the via openings 6 and 8, charges are separated by a thinner dielectric layer from the ground or virtual ground than on the top surface 10 of the dielectric layer 2. The leakage current at the bottom of the via openings 6 and 8, therefore, is greater, and more charges leak to the ground or virtual ground.

The difference in charge-retaining abilities causes the difference in the ability to repel secondary electrons. Locations having more accumulated electrons emit more secondary electrons, and thus are brighter in the VC image, while locations with less accumulated electrons emit less secondary electrons, and thus are darker in the VC image.

It has been found that there is a direct correlation between the gray levels of the via openings and the thicknesses of the remaining dielectric layer(s) at the bottom of vias, such as exemplary vias 6 and 8. Furthermore, the correlation is found to be linear.

The remaining thicknesses at the bottom of the via/contact openings can be estimated based on relative gray levels of the openings. If a first and a second opening have a first gray level and a second gray level respectively, and the second gray level is greater than the first gray level, the remaining thickness of the second opening can be determined based on the remaining thickness of the first opening and a ratio of the second gray level to the first gray level.

To more accurately determine the remaining thicknesses, the correlation needs to be construed in an accurate form through a calibration process, and the remaining thickness is expressed as the function of the gray level. Preferably, a calibration curve is drawn. Alternatively, the correlation can be expressed as a lookup table or a polynomial equation.

Multiple sample points need to be collected in order to construe the correlation. In the preferred embodiment, multiple sample wafers are fabricated. The process for forming the dielectric layer 2, CESL 4 and via openings 6 and 8 varies from wafer to wafer, so that via openings with different remaining thicknesses are obtained. In other embodiments, only one sample wafer is formed. The sample wafer preferably includes multiple groups having similar structures but different pattern densities. Due to micro-loading effects, variation occurs, causing different remaining thicknesses in different groups.

After the via openings on the sample wafers are formed, but before the etch stop layer is etched, the sample wafers are scanned using a scanning electron microscope, thus producing VC images. Gray levels of the via openings are determined from the VC images. The remaining thicknesses on the sample wafers are then measured, preferably using a method that can provide accurate thicknesses, for example, transmission electron microscopy (TEM).

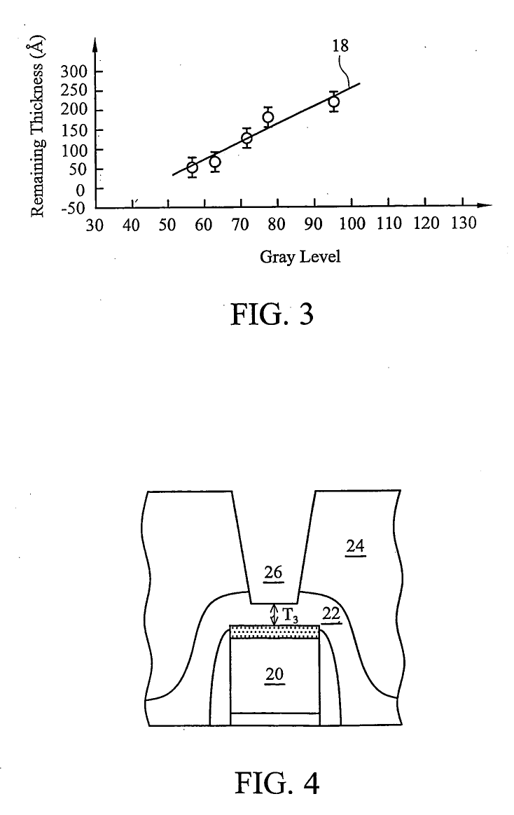

After enough sample points covering the desired range of the remaining thicknesses are collected, the correlation can be established, for example, by marking sample points on a graph and drawing a fit line (calibration curve). FIG. 3 illustrates a calibration curve produced using sample wafers. The X-axis shows the gray level, and the Y-axis shows the remaining thickness. In the illustrative example, sample points were obtained on etch stop layers formed using SiC. A calibration curve 18 is drawn. From the calibration curve 18, it is found that gray levels are proportional to the remaining thicknesses for the sample points collected, and the thicker the remaining thickness is, the brighter the opening is shown in the VC image. It is appreciated that such a linear correlation may not be found for other etch stop layers having different materials and thicknesses.

It is also appreciated that the correlation depends on the structures and materials. Therefore, the correlation is preferably construed using sample openings having substantially similar structures and dimensions and/or that are formed of substantially similar materials as the target openings whose remaining thicknesses are to be determined.

After being construed, the correlation can be used to determine the remaining thicknesses of via openings immediately after the via openings are formed. For example, if a via opening has a gray level of 70 in the VC image of the wafer, from FIG. 3, it can be determined that the remaining thickness of the CESL is about 110 Å.

Being able to determine the remaining thickness means that process variations can be quickly determined and analyzed. The respective process recipe can be evaluated in several minutes. Micro-loading effects and non-uniformity can be identified. If an undesired result is observed, fabrication processes can be adjusted. Since the remaining thickness is known, the CESL etching process can be adjusted precisely.

The preferred embodiment of the present invention can also be used to detect the remaining thickness of contact openings. Referring to FIG. 4, a contact opening 26 is formed in an inter-dielectric layer 24, which is in turn formed on a contact etch stop layer 22. A gate electrode 20 underlies the contact etch stop layer 22. In the preferred embodiment, the gate electrode 20 acts as a virtual ground. By determining the gray level of the opening 26 in the respective VC image and referring to a correlation construed for contact openings, the remaining thickness T₃ of the etch stop layer 22 can be determined.

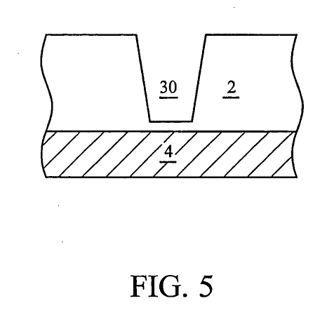

The preferred embodiments of the present invention can be used to measure small remaining thicknesses, for example, remaining dielectric layers with thicknesses less than about 50 Å. This significantly improves the accuracy of etching processes. Etch-through can also be detected. However, such an extension of detecting ability does not compromise its ability to determine large remaining thicknesses. If desired, preferred embodiments of the present invention can also be used to measure remaining thickness of several hundred angstroms or greater. An example is shown in FIG. 5, wherein a via opening 30 stops in the dielectric layer 2 overlying the etch stop layer 4. Using the previously discussed method, the remaining thickness of the combined dielectric layer 2 and etch stop layer 4 can be found.

Another advantageous feature of the preferred embodiments of the present invention is that the remaining thicknesses of the via/contact openings that have high aspect ratios, which are difficult to measure using conventional means, can be determined.

The preferred embodiments of the present invention are non-destructive, unlike the conventionally used analysis methods such as focus ion beam (FIB) and transmission electron microscopy (TEM).

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for determining a remaining thickness at the bottom of an opening in an integrated circuit, the method comprising:
providing a substrate;
forming a dielectric layer over the substrate;
forming an opening in the dielectric layer;
grounding the substrate;
scanning the substrate using a scanning electron microscope to produce a voltage contrast (VC) image;
determining a gray level of the opening in the VC image; and
using the gray level to determine the remaining thickness of the dielectric layer at the bottom of the opening.

2. The method of claim 1, wherein a virtually grounded region underlies the dielectric layer and the opening.

3. The method of claim 1 wherein the step of using the gray level to determine the remaining thickness comprises a calibration process to construe a correlation between gray levels and remaining thicknesses, and wherein the calibration process comprises:
forming sample openings;
using a scanning electron microscope to produce VC images of the sample openings;
determining gray levels of the sample openings from the VC images;
measuring remaining thicknesses at the bottom of the sample openings; and
establishing the correlation using the gray levels and the remaining thicknesses.

4. The method of claim 1, wherein the opening is a via opening.

5. The method of claim 1, wherein the opening is a contact opening.

6. The method of claim 1, wherein the dielectric layer comprises a sub dielectric layer and an etch stop layer underlying the sub dielectric layer, wherein the opening extends from a top surface of the sub dielectric layer into the etch stop layer.

7. The method of claim 1, wherein the remaining thickness is less than about 50 Å.

8. A method for determining a remaining thickness at the bottom of an opening in an integrated circuit, the method comprising:
providing a substrate;
forming an etch stop layer over the substrate;
forming a dielectric layer on the etch stop layer;
forming an opening in the dielectric layer extending from a top surface of the dielectric layer into the etch stop layer;
performing a calibration process to construe a correlation between gray levels and remaining thicknesses;
grounding the substrate;
scanning the substrate using a scanning electron microscope to produce a voltage contrast (VC) image;
determining a gray level of the opening in the VC image; and
using the gray level and the correlation to determine the remaining thickness of the etch stop layer at the bottom of the opening.

9. The method of claim 8, wherein the step of construing the correlation comprises:
forming a plurality of sample openings substantially similar to the opening;
determining sample gray levels of the sample openings;
measuring sample remaining thicknesses of the sample openings; and
construing the correlation between the sample gray levels and the sample remaining thicknesses.

10. The method of claim 9, wherein the correlation is expressed as a calibration curve.

11. The method of claim 8, wherein the scanning is performed using an ebeam having a landing energy of greater than 50 eV and less than a maximum sustainable landing energy.

12. The method of claim 8, wherein the dielectric layer is an inter-metal dielectric layer, and wherein the opening is a via opening.

13. The method of claim 8, wherein the dielectric layer is an inter-layer dielectric layer, and wherein the opening is a contact opening.

14. The method of claim 8, wherein the remaining thickness is less than about 50 Å.

15. A method for determining remaining thicknesses at the bottoms of openings in integrated circuits, the method comprising:
providing a first opening and a second opening;
scanning the first opening and the second opening using an eBeam to produce respective VC images;
determining a first gray level of the first opening and a second gray level of the second opening from the VC images;
measuring a remaining thickness of the first opening; and
determining a second remaining thickness of the second opening using the first remaining thickness and a ratio of the first gray level to the second gray level.

16. The method of claim 15 further comprising:
providing a third opening substantially similar to the first opening;
scanning the third opening using an eBeam to produce an additional VC image;
determining a third gray level of the third opening from the additional VC image, wherein the third gray level is between the first and the second gray levels; and
determining the third remaining thickness to be between the first and the second remaining thicknesses.

17. The method of claim 15, wherein the first opening and the second opening are on a same wafer.

18. The method of claim 15, wherein the first opening and the second are on different wafers.
